(19) United States
(12) Patent Application Publication
(10) Pub. No.: US 2026/0032908 A1
(43) Pub. Date: Jan. 29, 2026

(54) SEMICONDUCTOR DEVICE AND MANUFACTURING METHOD OF SEMICONDUCTOR DEVICE

(71) Applicant: SK hynix Inc., Gyeonggi-do (KR)

(72) Inventors: Na Yeong YANG, Gyeonggi-do (KR); Jung Shik JANG, Gyeonggi-do (KR); Seok Min CHOI, Gyeonggi-do (KR); Won Geun CHOI, Gyeonggi-do (KR)

(21) Appl. No.: 18/916,703

(22) Filed: Oct. 16, 2024

(30) Foreign Application Priority Data
Jul. 25, 2024 (KR) 10-2024-0098556

(51) Int. Cl. H10B 43/27; H01L 23/00; H01L 25/065; H01L 25/18; H10B 41/27; H10B 80/00

(52) U.S. Cl. CPC H10B 43/27; H01L 24/08; H01L 25/0657; H01L 25/18; H10B 41/27; H10B 80/00; H01L 2224/08145; H01L 2924/1431; H01L 2924/14511

(57) ABSTRACT

A semiconductor device may include a gate structure including conductive layers and insulating layers that are alternately stacked; a first contact plug including a first main portion extended by a first depth through the gate structure and a first extension portion connected to the first main portion and having a sidewall with a staircase shape, the first contact plug being electrically connected to a first conductive layer of the conductive layers; and a second contact plug including a second main portion extended by a second depth greater than the first depth through the gate structure and a second extension portion connected to the second main portion and having a sidewall with a staircase shape, the second contact plug being electrically connected to a second conductive layer of the conductive layers, wherein the second extension portion may have a greater width than the first extension portion.

### CROSS-REFERENCE TO RELATED APPLICATION

This application claims priority under 35 U.S.C. § 119 to Korean Patent Application No. 10-2024-0098556 filed on Jul. 25, 2024, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, to improve the operational reliability of such a semiconductor device, various structures and manufacturing methods have been developed.

### SUMMARY

In an embodiment of the present disclosure, a semiconductor device may include a gate structure including conductive layers and insulating layers that are alternately stacked; a first contact plug including a first main portion extended by a first depth through the gate structure and a first extension portion connected to the first main portion and having a sidewall with a staircase shape, the first contact plug being electrically connected to a first conductive layer of the conductive layers; and a second contact plug including a second main portion extended by a second depth greater than the first depth through the gate structure and a second extension portion connected to the second main portion and having a sidewall with a staircase shape, the second contact plug electrically connected to a second conductive layer of the conductive layers, wherein the second extension portion may have a greater width than the first extension portion.

In an embodiment of the present disclosure, a manufacturing method of a semiconductor device may include forming a first contact hole in a stack, the first contact hole having a first depth and a first width; forming a second contact hole in the stack, the second contact hole having a second depth greater than the first depth and a second width greater than the first width; forming a first polymer layer in the first contact hole, the first polymer layer having a first thickness; forming a second polymer layer in the second contact hole, the second polymer layer having a second thickness less than the first thickness; extending the first contact hole into the stack by etching the first polymer layer and the stack; and extending the second contact hole into the stack by etching the second polymer layer and the stack.

In an embodiment of the present disclosure, a manufacturing method of a semiconductor device may include forming a contact hole in a stack; forming a first polymer layer in the contact hole; extending the contact hole into the stack by etching the first polymer layer and the stack; forming a second polymer layer in the extended contact hole; and additionally extending the extended contact hole into the stack by etching the second polymer layer and the stack, wherein an extended portion of the additionally extended contact hole may have a smaller width than an extended portion of the extended contact hole.

### BRIEF DESCRIPTION OF THE DRAWINGS

FIGS. 1A and 1B are diagrams for describing the structure of a semiconductor device in accordance with an embodiment of the present invention.

FIGS. 2A and 2B are diagrams illustrating the structure of a semiconductor device in accordance with an embodiment of the present invention.

FIG. 3 is a diagram illustrating the structure of a semiconductor device in accordance with an embodiment of the present invention.

FIGS. 4A to 4E are diagrams for describing a manufacturing method of a semiconductor device in accordance with an embodiment of the present invention.

FIGS. 5A to 5E are diagrams for describing a manufacturing method of a semiconductor device in accordance with an embodiment of the present invention.

FIGS. 6A to 6F are diagrams illustrating a manufacturing method of a semiconductor device in accordance with an embodiment of the present invention.

FIG. 7 is a configuration diagram of a semiconductor device in accordance with an embodiment of the present invention.

FIG. 8 is a configuration diagram of a semiconductor device in accordance with an embodiment of the present invention.

### DETAILED DESCRIPTION

Various embodiments of the present disclosure are directed to a semiconductor device having a stable structure and improved characteristics and a manufacturing method of the semiconductor device.

By stacking memory cells in three dimensions, it is possible to improve the degree of integration of a semiconductor device. It is also possible to provide a semiconductor device having a stable structure and improved reliability.

Hereafter, embodiments in accordance with the technical spirit of the present disclosure will be described with reference to the accompanying drawings.

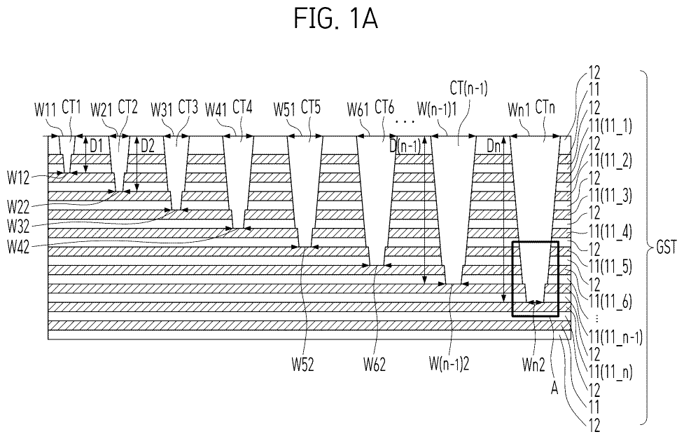

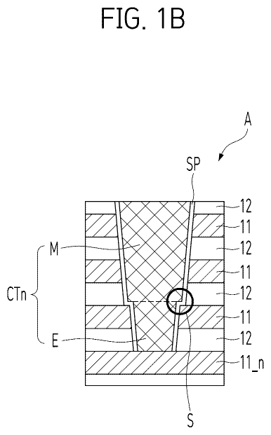

FIGS. 1A and 1B are diagrams for describing the structure of a semiconductor device in accordance with an embodiment of the present invention. FIG. 1B is an enlarged view of region A of FIG. 1A. Referring to FIGS. 1A and 1B, the semiconductor device may

include a gate structure GST and a plurality of contact plugs CT1 to CTn extending into the gate structure GST at various depths thereof. The semiconductor device may include first to n-th contact plugs CT1 to CTn, and n may be an integer of 2 or more.

The gate structure GST may include conductive layers 11 and insulating layers 12 that are alternately stacked. The conductive layers 11 may be gate lines such as drain select lines, word lines, or source select lines. The conductive layers 11 may each include a conductive material such as polysilicon or metal. The insulating layers 12 may insulate the stacked gate lines from each other. The insulating layers 12 may each include an oxide, a nitride, an air gap, or the like, or any combination thereof.

The contact plugs CT1 to CTn may be interconnection structures for applying a bias to the stacked gate lines. Insulating spacers SP may surround the sidewalls of the contact plugs CT1 to CTn. More specifically an insulating spacer may surround the sidewall of each of the contact plugs CT1 to CTn. The contact plugs CT1 to CTn may be electrically connected to the conductive layers 11_1 to 11_n, respectively. The first contact plug CT1 may be electrically connected to a first conductive layer 11_1 and may be insulated from the remaining conductive layers 11. The second contact plug CT2 may be electrically connected to a second conductive layer 11_2 and may be insulated from the remaining conductive layers 11. The n-th contact plug CTn may be electrically connected to an n-th conductive layer 11_n and may be insulated from the remaining conductive layers 11.

The contact plugs CT1 to CTn may extend into the gate structure GST at different depths, and the upper surfaces of the contact plugs CT1 to CTn may have different widths. The greater the depths at which the contact plugs CT1 to CTn extend into the gate structure GST, the greater the widths of the upper surfaces of the contact plugs CT1 to CTn may be. As an example, the first contact plug CT1 may extend through the gate structure GST by a first depth D1, and an upper surface of the first contact plug CT1 may have a first width W11. The second contact plug CT2 may extend through the gate structure GST by a second depth D2 greater than the first depth D1, and an upper surface of the second contact plug CT2 may have a second width W21 greater than the first width W11. The n-th contact plug CTn may extend through the gate structure GST by an n-th depth Dn greater than an (n−1)th depth D(n−1), and an upper surface of the n-th contact plug CTn may have an n-th width Wn1 greater than an (n−1)-th width W(n−1)1.

Each of the contact plugs CT1 to CTn may include a main portion M and an extension portion E. The main portion M may extend from an upper surface of the gate structure GST. The extension portion E may be connected to the main portion M, and may have a smaller width than the main portion M. Sidewalls of the main portion M and the extension portion E may be surrounded by the insulating spacer SP, and a bottom surface of the extension portion E may be electrically connected to the corresponding conductive layer 11. A step S may be formed due to a width difference between the main portion M and the extension portion E, and at least one of the contact plugs CT1 to CTn may include the step S on a sidewall thereof.

The main portions M of the contact plugs CT1 to CTn may extend into the gate structure GST at different depths. The main portion M of the second contact plug CT2 may extend at a greater depth than the main portion M of the first contact plug CT1. The main portion M of the n-th contact plug CTn may extend at a greater depth than the main portion M of the (n−1)-th contact plug CT(n−1). The extension portions E of the contact plugs CT1 to CTn may have substantially the same height.

The extension portions E of the contact plugs CT1 to CTn may have different widths. The greater the depths of the contact plugs CT1 to CTn, the greater the widths of the bottom surfaces of the extension portions E may be. The extension portion E of the first contact plug CT1 may have a first width W12, and the extension portion E of the second contact plug CT2 may have a second width W22 greater than the first width W12. The extension portion E of the (n−1)-th contact plug CT(n−1) may have an (n−1)-th width W(n−1)2, and the extension portion E of the n-th contact plug CTn may have an n-th width Wn2 greater than the (n−1)-th width W(n−1)2.

The sidewalls of the contact plugs CT1 to CTn may each have a staircase shape due to the step S. Each of the contact plugs CT1 to CTn may have a symmetrical staircase shape or an asymmetrical staircase shape. As an example, each of the contact plugs CT1 to CTn may have substantially the same staircase shape or different staircase shapes on one side and the other side thereof based on a central axis.

According to the structure described above, the contact plugs CT1 to CTn may extend through the gate structure GST, and may each be connected to a different conductive layer 11. The greater the depth at which a contact plug CT1 to CTn extends, the greater its width may be. Each one of contact plugs CT1 to CTn may include a main portion M, and an extension portion E extending from the main portion M. As illustrated in FIG. 1A, the depths of the contact plugs CT1 to CTn may be adjusted through the main portions M, while the extension portions E may have the same height. However, it is understood that in a variation of this embodiment the depths of the contact plugs CT1 to CTn may be adjusted through the main portions M and the extension portions E.

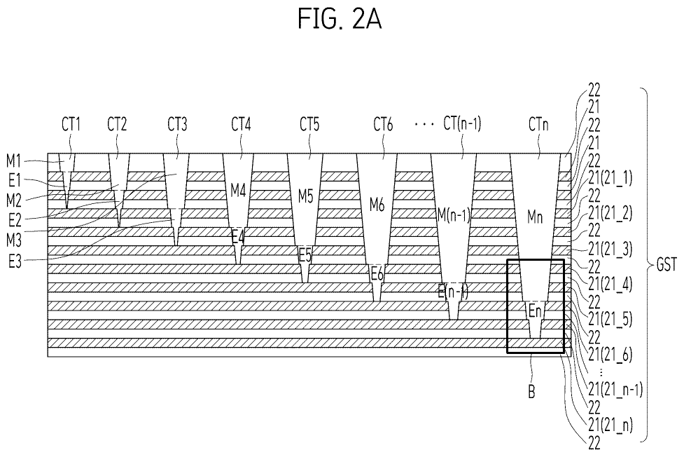

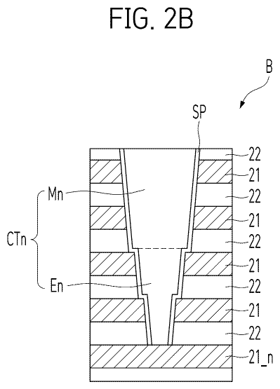

FIGS. 2A and 2B are diagrams illustrating the structure of a semiconductor device in accordance with an embodiment of the present invention. FIG. 2B is an enlarged view of region B of FIG. 2A. Hereinafter, a content overlapping previously described content may be omitted.

Referring to FIGS. 2A and 2B, the semiconductor device may include a gate structure GST, first to n-th contact plugs CT1 to CTn extending in the gate structure to different depths, and insulating spacers SP surrounding the sidewalls of the contact plugs. For example, n may be an integer of 2 or more. The gate structure GST may include conductive layers 21 and insulating layers 22 that are alternately stacked.

The first to n-th contact plugs CT1 to CTn may each be electrically connected to a different one of the first to n-th conductive layers 21_1 to 21_n, respectively. For example, the first to n-th contact plugs CT1 to CTn may be electrically connected to the first to n-th conductive layers 21_1 to 21_n, respectively. The respective contact plugs CT1 to CTn may include main portions M1 to Mn and extension portions E1 to En. A second main portion M2 may extend at a greater depth than a first main portion M1, and an n-th main portion Mn may extend at a greater depth than a (n−1)-th main portion M(n−1). A first extension portion E1 may have a smaller width than the first main portion M1, and an n-th extension portion En may have a smaller width than the n-th main portion Mn. The first to n-th extension portions E1 to En may have the same height. Stated differently, the first to n-th extension portions E1 to En may extend for a same depth inside the gate structure but because of the different height of the main portions M1 to Mn, the lower ends of the extension portions may be located at different depths.

Each of the extension portions E1 to En may have a sidewall with a staircase shape. The extension portions E1 to En may have widths that decrease as they become closer to a lower surface of the gate structure GST. Heights of respective layers (e.g., steps) of the staircase shapes may be the same as each other. As an example, each layer may include a conductive layer 21 and an insulating layer 22.

The extension portions E1 to En included in different contact plugs CT1 to CTn may have the same staircase shape. The first to n-th extension portions E1 to En may extend for the same depth, and the heights (also referred to as lengths) of the respective layers of the staircase shapes of the first to n-th extension portions E1 to En may be the same as each other. However, the widths of the extension portions E1 to En may be different. A width of a bottom surface of the second extension portion E2 may be greater than a width of a bottom surface of the first extension portion E1, and a width of a bottom surface of the n-th extension portion En may be greater than a width of a bottom surface of the (n−1)-th extension portion E(n−1).

It is noted, that in variations of the described embodiment, it is possible for the extension portions E1 to En included in the different contact plugs CT1 to CTn to have different staircase shapes. The first to n-th extension portions E1 to En may extend for a different depth (or distance or length or height) inside the gate structure (GST) or the heights of the respective layers of the staircase shapes of the first to n-th extension portions E1 to En may be different from each other. Also, in a variation of the described embodiment, each of the first to n-th extension portions E1 to En may have an asymmetric staircase shape. Each of the extension portions E1 to En may have different staircase shapes on one side and the other side thereof based on a central axis.

According to the structure described above, the contact plugs CT1 to CTn may extend through the gate structure GST, and may be connected to different conductive layers 21. The respective contact plugs CT1 to CTn may include the main portions M1 to Mn and the extension portions E1 to En, with the extension portions E1 to En having staircase shape sidewalls.

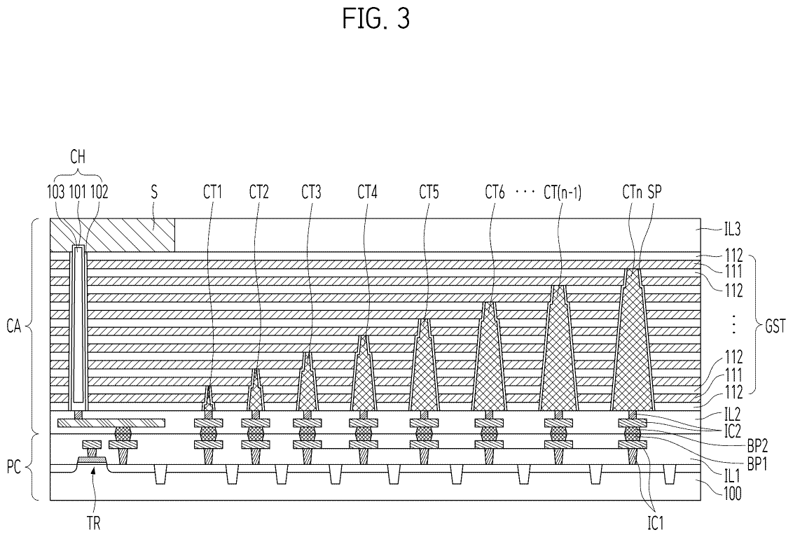

FIG. 3 is a diagram illustrating the structure of a semiconductor device in accordance with an embodiment of the present disclosure. Hereinafter, a content overlapping previously described content may be omitted.

Referring to FIG. 3, the semiconductor device may include a peripheral circuit PC and a memory cell array CA disposed over the peripheral circuit PC. The memory cell array CA may be located on the peripheral circuit PC. The peripheral circuit PC and the memory cell array CA may be electrically connected to each other. The peripheral circuit PC and the memory cell array CA may be electrically connected to each other through bonding pads BP1 and BP2.

The memory cell array CA may include a source structure S, a gate structure GST, and a channel structure CH. The source structure S and a third interlayer insulating layer IL3 may be located on the gate structure GST. The gate structure GST may include conductive layers 111 and insulating layers 112 that are alternately stacked. The channel structure CH may extend into the source structure S through the gate structure GST. The channel structure CH may include a channel layer 101, a memory layer 102 surrounding the channel layer 101, and an insulating layer 103 located in the channel layer 101. The channel layer 101 may be connected to the source structure S.

Contact plugs CT1 to CTn may extend through the gate structure GST, and may be electrically connected to different conductive layers 111. The contact plugs CT1 to CTn may include steps on sidewalls thereof. Insulating spacers SP may surround the sidewalls of the contact plugs CT1 to CTn.

A second interconnection structure IC2 may be located in a second interlayer insulating layer IL2, and may include a via, a wiring line, and the like. The second interconnection structure IC2 may be electrically connected to the memory cell array CA through the contact plugs CT1 to CTn.

The peripheral circuit PC may be a circuit for driving the memory cell array CA, and may include a page buffer, a row decoder, and the like. As an example, the peripheral circuit PC may include a transistor TR located on a substrate 100.

A first interconnection structure IC1 may be located in a first interlayer insulating layer IL1, and may include a via, a wiring line, and the like. The first interconnection structure IC1 may be electrically connected to the peripheral circuit PC.

A first bonding pad BP1 and a second bonding pad BP2 may be located at an interface between the peripheral circuit PC and the memory cell array CA. The first bonding pad BP1 and the second bonding pad BP2 may be at the first and second interlayer insulating layers IL1 and IL2 respectively. The first bonding pad BP1 may be electrically connected to the first interconnection structure IC1, and the second bonding pad BP2 may be electrically connected to the second interconnection structure IC2. The first bonding pad BP1 and the second bonding pad BP2 may be bonded to each other to electrically connect the peripheral circuit PC and the memory cell array CA to each other.

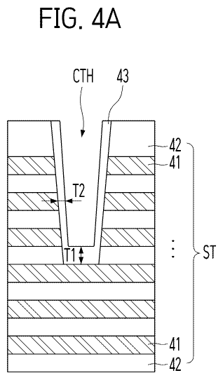

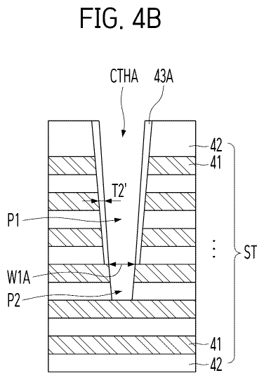

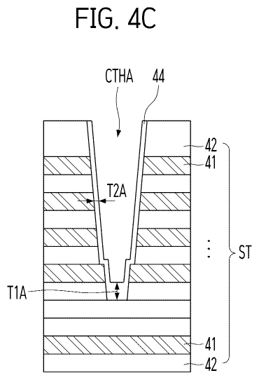

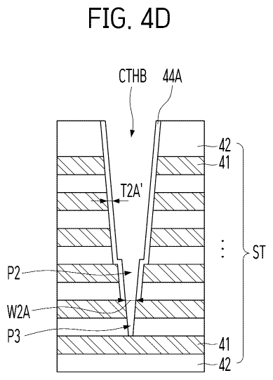

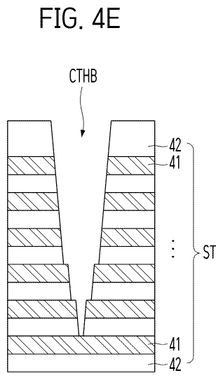

FIGS. 4A to 4E are diagrams for describing a manufacturing method of a semiconductor device in accordance with an embodiment of the present disclosure. Hereinafter, a content overlapping previously described content will be omitted.

Referring to FIG. 4A, a stack ST including first material layers 41 and second material layers 42 that are alternately stacked may be formed. The first material layers 41 may be used to form gate lines, and the second material layers 42 may be used to form insulating layers for insulating the stacked gate lines from each other. The first material layers 41 may each include a material having a high etching selectivity with respect to the second material layers 42. As an example, the first material layers 41 may each include a sacrificial material such as nitride or a conductive material such as polysilicon or metal. The second material layers 42 may each include an insulating material such as oxide, nitride, or air gap.

Subsequently, a contact hole CTH may be formed in the stack ST. The contact hole CTH may extend through the stack ST, and may expose the first material layer 41 on a bottom surface thereof. As an example, a plurality of contact holes CTH having different depths may be formed in the stack ST.

Subsequently, a first polymer layer 43 may be formed in the contact hole CTH. The first polymer layer 43 may be formed conformally along an inner surface of the contact hole CTH. The first polymer layer 43 may be formed by depositing a by-product generated in a plasma treatment process on the inner surface of the contact hole

CTH. As an example, the plasma treatment process may be performed using a combination of a first gas generating a nonvolatile by-product and a second gas generating a volatile by-product. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The first polymer layer 43 may be formed by performing the plasma treatment process using polymer-rich plasma in which a content of the first gas is higher than a content of the second gas.

The first polymer layer 43 may be formed to have different thicknesses depending on regions. When the first polymer layer 43 is formed at a high temperature, adsorption force of a polymer may be lower than when the first polymer layer 43 is formed at a low temperature, and the polymer may be mainly deposited on the bottom surface of the contact hole CTH rather than an inner side wall of the contact hole CTH. In such a case, the first polymer layer 43 may have a second thickness T2 on the inner side wall of the contact hole CTH, and may have a first thickness T1 greater than the second thickness T2 on the bottom surface of the contact hole CTH.

Referring to FIG. 4B, the contact hole CTH may be extended by etching the first polymer layer 43 and the stack ST. A portion of the first polymer layer 43 formed on the bottom surface of the contact hole CTH may be etched, and the first material layer 41 may be exposed on the bottom surface of the contact hole CTH. Subsequently, the contact hole CTH may be extended by sequentially etching the first material layer 41 and the second material layer 42. The extended contact hole CTHA may expose the first material layer 41.

The extension of the contact hole CTH may be performed by a plasma treatment process using a combination of a first gas and a second gas. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The contact hole CTH may be extended by performing the plasma treatment process using etchant-rich plasma in which a content of the second gas is higher than a content of the first gas.

The extended contact hole CTHA may include a first portion P1 that corresponds to the existing contact hole CTH and a second portion P2 that is extended. At a point where the first portion P1 and the second portion P2 are connected to each other, widths of the first portion P1 and the second portion P2 may be the same as or different from each other. As an example, a width W1A of the second portion P2 may be less than a width of the first portion P1, and a step may exist on a sidewall of the extended contact hole CTHA.

A first polymer layer 43A may remain on an inner side wall of the extended contact hole CTHA. In a process of extending the contact hole CTH, the first polymer layer 43 formed on the inner side wall of the contact hole CTH may be partially etched, and the remaining first polymer layer 43A may have a second thickness T2′ less than the second thickness T2. A width difference between the first portion P1 and the second portion P2 may correspond to a width of the remaining first polymer layer 43A. When the thickness of the remaining first polymer layer 43A is great, the width difference may be great, and when the thickness of the remaining first polymer layer 43A is small, the width difference may be small.

Referring to FIG. 4C, the remaining first polymer layer 43A may be removed. Subsequently, a second polymer layer 44 may be formed in the extended contact hole CTHA. The second polymer layer 44 may be formed along an inner surface of the extended contact hole CTHA.

The second polymer layer 44 may be formed by depositing a by-product generated in a plasma treatment process on the inner surface of the contact hole CTHA. As an example, the plasma treatment process may be performed using a combination of a first gas generating a nonvolatile by-product and a second gas generating a volatile by-product. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The second polymer layer 44 may be formed by performing the plasma treatment process using polymer-rich plasma in which a content of the first gas is higher than a content of the second gas.

The second polymer layer 44 may be formed to have different thicknesses depending on regions. The second polymer layer 44 may have a second thickness T2A on the inner side wall of the contact hole CTHA, and may have a first thickness T1A greater than the second thickness T2A on a bottom surface of the contact hole CTHA.

Referring to FIG. 4D, the contact hole CTHA may be additionally extended by etching the second polymer layer 44 and the stack ST. A portion of the second polymer layer 44 formed on the bottom surface of the contact hole CTHA may be etched, and the first material layer 41 may be exposed on the bottom surface of the contact hole CTHA. Subsequently, the contact hole CTHA may be additionally extended by sequentially etching the first material layer 41 and the second material layer 42 to form a contact hole CTHB. The additionally extended contact hole CTHB may expose the first material layer 41.

The extension of the contact hole CTHA may be performed by a plasma treatment process using a combination of a first gas and a second gas. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The contact hole CTHA may be additionally extended by performing the plasma treatment process using etchant-rich plasma in which a content of the second gas is higher than a content of the first gas.

The additionally extended contact hole CTHB may include a third portion P3 that is additionally extended. At a point where the second portion P2 and the third portion P3 are connected to each other, widths of the second portion P2 and the third portion P3 may be the same as or different from each other. As an example, a width W2A of the third portion P3 may be less than a width of the second portion P2.

A second polymer layer 44A may remain on an inner side wall of the additionally extended contact hole CTHB. In a process of extending the contact hole CTHA, the second polymer layer 44 formed on the inner side wall of the contact hole CTHA may be partially etched, and the remaining second polymer layer 44A may have a second thickness T2A′ less than the second thickness T2A. A width difference between the second portion P2 and the third portion P3 may correspond to a width of the remaining second polymer layer 44A. When the thickness of the remaining second polymer layer 44A is great, the width difference may be great, and when the thickness of the remaining second polymer layer 44A is small, the width difference may be small.

Referring to FIG. 4E, the remaining second polymer layer 44A may be removed. Through this, the additionally extended contact hole CTHB may be formed. By repeatedly extending the contact hole CTHB, the contact hole CTHB may include a staircase shape on a sidewall thereof.

According to the manufacturing method described above, the contact hole CTHB may be extended using polymer layer forming and etching processes. In addition, by repeatedly performing the polymer layer forming and etching processes, it is possible to form the contact hole CTHB having a desired depth.

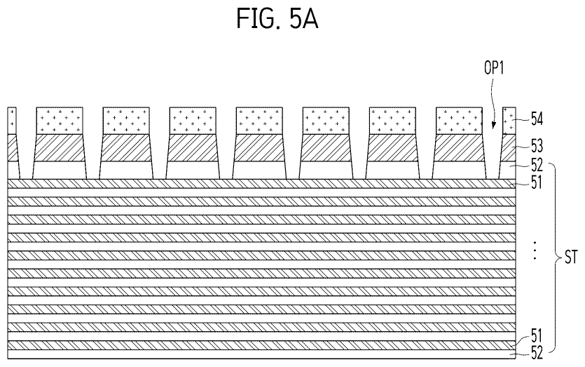

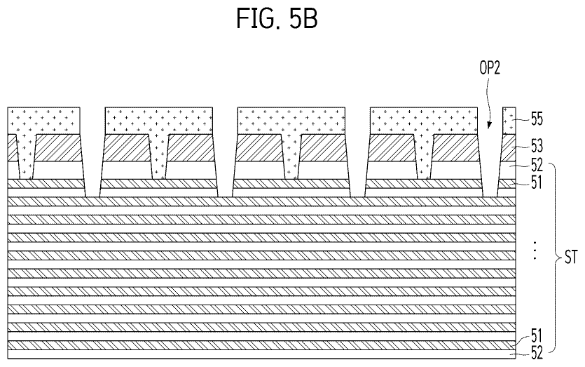

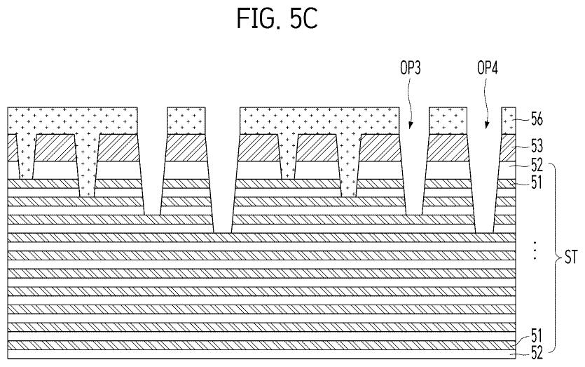

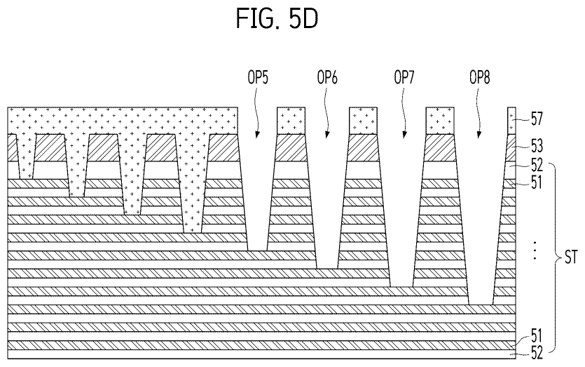

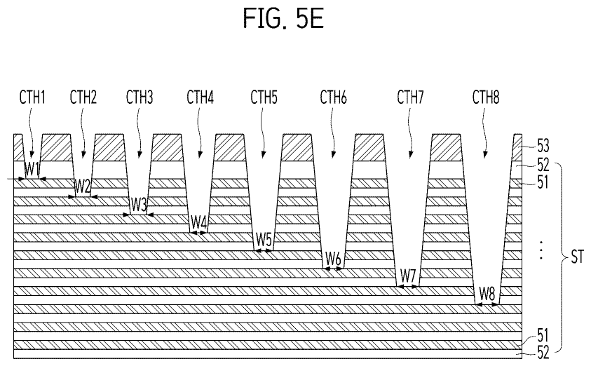

FIGS. 5A to 5E are diagrams for describing a manufacturing method of a semiconductor device in accordance with an embodiment of the present disclosure, and illustrate a method of forming a contact hole. Hereinafter, a content overlapping previously described content may be omitted.

Referring to FIG. 5A, a stack ST including first material layers 51 and second material layers 52 that are alternately stacked may be formed. The first material layers 51 may each include a sacrificial material or a conductive material, and the second material layers 52 may each include an insulating material. Subsequently, a hard mask layer may be formed on the stack ST. The hard mask layer may include a material having a high etching selectivity with respect to the first and second material layers 51 and 52. The hard mask layer may include polysilicon. Subsequently, a first photoresist pattern 54 may be formed on the hard mask layer. Subsequently, a hard mask pattern 53 may be formed by etching the hard mask layer using the first photoresist pattern 54 as an etching barrier.

Subsequently, a plurality of first openings OP1 may be formed spaced apart at a regular interval by etching the stack ST using the first photoresist pattern 54 and the hard mask pattern 53 as an etching barrier. The first openings OP1 may have a depth at which they expose the uppermost first material layer 51. The first openings OP1 may have substantially the same width.

Referring to FIG. 5B, the first photoresist pattern 54 may be removed, and a second photoresist pattern 55 may be formed on the hard mask pattern 53. The second photoresist pattern 55 may be formed to cover only some of the first openings OP1 and expose the remaining the first openings OP1. Subsequently, the stack ST may be etched using the second photoresist pattern 55 and the hard mask pattern 53 as an etching barrier. Through this, the exposed first openings OP1 may be extended into the stack ST, and second openings OP2 may be formed. The second openings OP2 may have the same width as or a greater width than the first openings OP1.

Referring to FIG. 5C, the second photoresist pattern 55 may be removed. Subsequently, a third photoresist pattern 56 may be formed on the hard mask pattern 53. The third photoresist pattern 56 may be formed to cover only some of the first openings OP1 and the second openings OP2 and expose the remaining ones of the first openings OP1 and the second openings OP2. Subsequently, the stack ST may be etched using the third photoresist pattern 56 and the hard mask pattern 53 as an etching barrier. Through this, the exposed first openings OP1 may be extended to form third openings OP3, and the exposed second openings OP2 may be extended to form fourth openings OP4. The third openings OP3 may have the same width as or a greater width than the first openings OP1. The fourth openings OP4 may have the same width as or a greater width than the second openings OP2.

Referring to FIG. 5D, the third photoresist pattern 56 may be removed. Subsequently, a fourth photoresist pattern 57 may be formed on the hard mask pattern 53. The fourth photoresist pattern 57 may be formed to cover only some of the first to fourth openings OP1 to OP4 and expose the remaining ones of the first to fourth openings OP1 to OP4.

Subsequently, the stack ST may be etched using the fourth photoresist pattern 57 and the hard mask pattern 53 as an etching barrier. Through this, the exposed first opening OP1 may be extended to form a fifth opening OP5, the exposed second opening OP2 may be extended to form a sixth opening OP6, the exposed third opening OP3 may be extended to form a seventh opening OP7, and the exposed fourth opening OP4 may be extended to form an eighth opening OP8. The fifth opening OP5 may have the same width as or a greater width than the first opening OP1. The sixth opening OP6 may have the same width as or a greater width than the second opening OP2 The seventh opening OP7 may have the same width as or a greater width than the third opening OP3. The eighth opening OP8 may have the same width as or a greater width than the fourth opening OP4.

Referring to FIG. 5E, the fourth photoresist pattern 57 may be removed. Through this, the first to eighth openings OP1 to OP8 having different depths may be formed. For example, the first to eighth openings OP1 to OP8 may be contact holes for forming contact plugs. The first to eighth openings OP1 to OP8 may be first to eighth contact holes CTH1 to CTH8. The first to eighth contact holes CTH1 to CTH8 may have different depths, and may expose different first material layers 51, respectively.

The first to eighth contact holes CTH1 to CTH8 may have substantially the same width or different widths. A contact hole having a greater depth may have a greater width than a contact hole having a smaller depth. A width difference between the contact holes may be due to the repetition number of times of etching, and the more the repetition number of times of etching of the contact hole, the greater the width of the contact hole may be. As an example, the eighth contact hole CTH8 may have a greater depth and width than the first contact hole CTH1.

According to the manufacturing method described above, a plurality of contact holes CTH1 to CTH8 having different depths may be formed. The contact holes CTH1 to CTH8 may have different widths, and the contact hole having the greater depth may have the greater width than the contact hole having the smaller depth. For example, it has been described in the present embodiment that the contact holes CTH1 to CTH8 are arranged in order of depth, but it is also possible for the contact holes to be arranged randomly regardless of the depth.

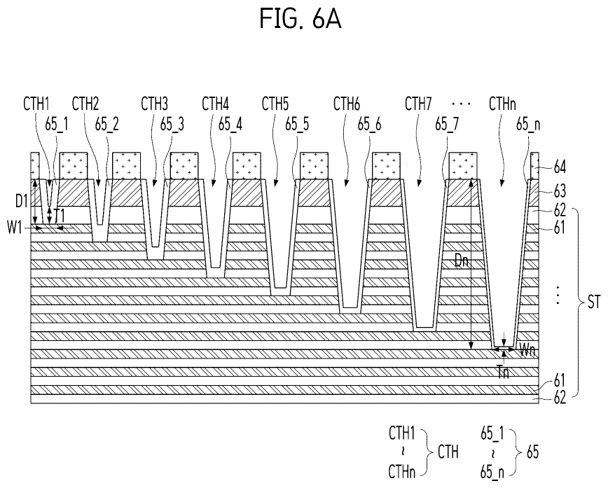

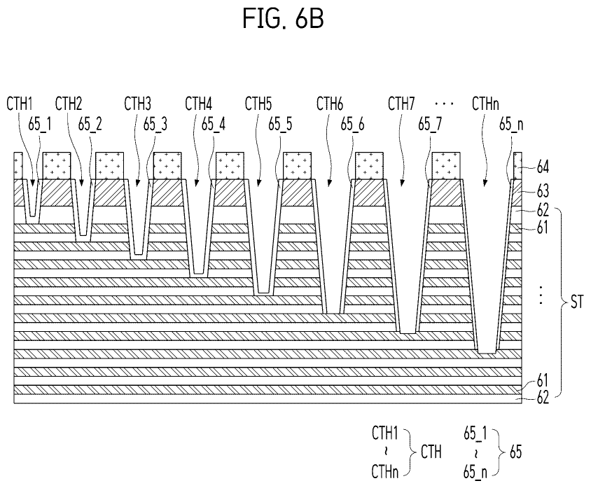

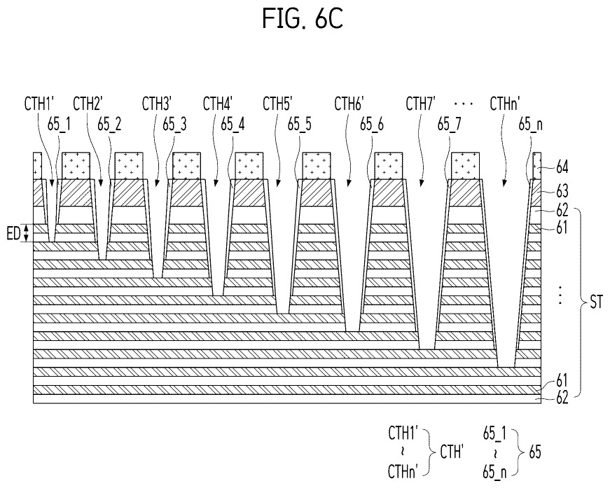

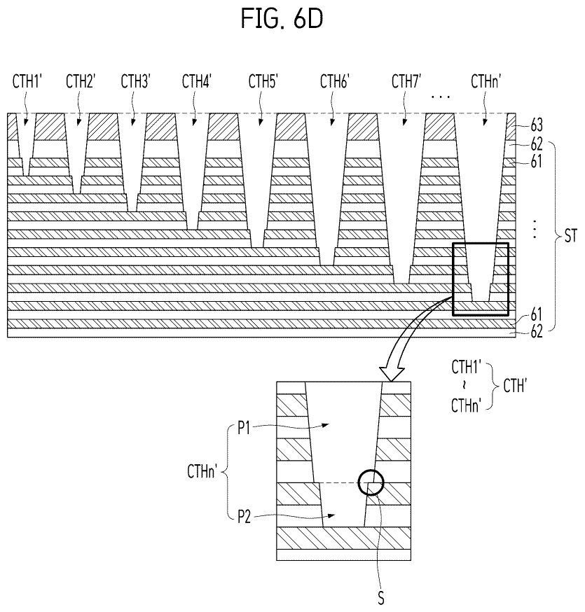

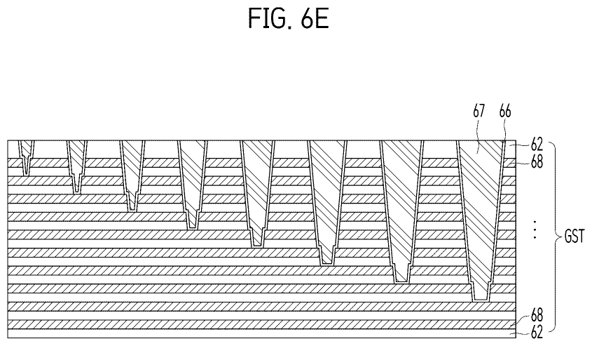

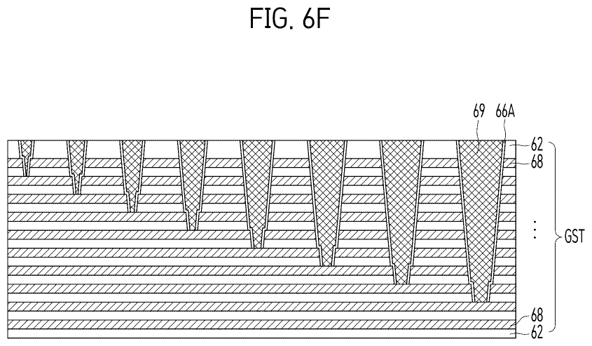

FIGS. 6A to 6F are diagrams illustrating a manufacturing method of a semiconductor device in accordance with an embodiment of the present disclosure, and illustrate a method of extending a contact hole. Hereinafter, a content overlapping previously described content may be omitted.

Referring to FIG. 6A, a plurality of contact holes CTH may be formed in a stack ST. As an example, the stack ST including first material layers 61 and second material layers 62 may be formed, and a hard mask pattern 63 may be formed on the stack ST. Subsequently, first to n-th contact holes CTH1 to CTHn having different depths may be formed by etching the stack ST using the hard mask pattern 63 as an etching barrier. The contact holes CTH may expose different first material layers 61, respectively. The first contact hole CTH1 may have a first depth D1, and a bottom surface of the first contact hole CTH1 may have a first width W1. The n-th contact hole CTHn may have an n-th depth Dn greater than the first depth D1, and a bottom surface of the n-th contact hole CTHn may have an n-th width Wn greater than the first width W1. For example, n may be an integer of 2 or more.

Subsequently, a photoresist pattern 64 may be formed on the hard mask pattern 63. The photoresist pattern 64 may be formed to expose contact holes CTH that are to be extended. The exposed contact holes CTH may have different depths.

Subsequently, polymer layers 65 may be formed in the contact holes CTH. The polymer layers 65 may be formed along inner surfaces of the contact holes CTH, and might not be formed on the photoresist pattern 64.

The polymer layers 65 may be formed by performing a plasma treatment process using a combination of a first gas generating a nonvolatile by-product and a second gas generating a volatile by-product. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The plasma treatment process may be performed using polymer-rich plasma in which a content of the first gas is higher than a content of the second gas.

As an example, a first polymer layer 65_1 may be formed in the first contact hole CTH1. The first polymer layer 65_1 may be formed to have different thicknesses depending on regions. The first polymer layer 65_1 may be formed thicker on the bottom surface of the first contact hole CTH1 than on an inner side wall of the first contact hole CTH1. The first polymer layer 65_1 may have a first thickness T1 on the bottom surface.

An n-th polymer layer 65_n may be formed in the n-th contact hole CTHn. When the first polymer layer 65_1 is formed, the n-th polymer layer 65_n may be formed. The n-th polymer layer 65_n may be formed thicker on the bottom surface of the n-th contact hole CTHn than on an inner side wall of the n-th contact hole CTHn. The n-th polymer layer 65_n may have an n-th thickness Tn on the bottom surface.

The first polymer layer 65_1 and the n-th polymer layer 65_n may have different thicknesses. A thickness difference between the first polymer layer 65_1 and the n-th polymer layer 65_n may be due to a difference in deposition environment. The n-th contact hole CTHn may have a relatively deep and wide shape, while the first contact hole CTH1 may have a relatively shallow and narrow shape. Accordingly, due to the difference in the deposition environment, a polymer may be deposited more in the first contact hole CTH1, and the first polymer layer 65_1 may have a greater thickness than the n-th polymer layer 65_n. The n-th thickness Tn may be less than the first thickness T1.

Referring to FIGS. 6B and 6C, the contact holes CTH may be extended into the stack ST by etching the polymer layers 65 and the stack ST. In this case, the contact holes CTH may be extended by the same depth. The extended contact holes CTH′ may have different depths, and may expose different first material layers 61, respectively.

The extension of the contact hole CTH may be performed by a plasma treatment process using a combination of a first gas and a second gas. The first gas may be CₓF_{y}, CₓF_{y}H_{z}, or the like, and may generate a carbon-based polymer. The second gas may be an inert gas such as Ar, Kr, or Xe, or may be NF₃, SF₆, or the like. The contact hole CTH may be extended by performing the plasma treatment process using etchant-rich plasma in which a content of the second gas is higher than a content of the first gas.

First, referring to FIG. 6B, the polymer layers 65 in the respective contact holes CTH may be etched. The first to n-th polymer layers 65_1 to 65_n may be etched simultaneously in the first to n-th contact holes CTH1 to CTHn. In this case, etch rates are different from each other depending on depths of the contact holes CTH. During an etching process, ion energy required to reach the bottom surface of the first contact hole CTH1 having a relatively small depth is greater than ion energy required to reach the bottom surface of the n-th contact hole

CTHn which has a relatively great depth. Accordingly, an etch rate of the first contact hole CTH1 is higher than an etch rate of the n-th contact hole CTHn.

When the first polymer layer 65_1 and the n-th polymer layer 65_n have the same thickness, the first polymer layer 65_1 of the first contact hole CTH1 having a high etch rate is etched faster than the n-th polymer layer 65_n, and the stack ST is exposed faster on the bottom surface of the first contact hole CTH1 than on the bottom surface of the n-th contact hole CTHn. In such a case, the stack ST is etched deeper in the contact hole where the stack ST is exposed faster, and thus, extension depths of the contact holes CTH become different from each other. The smaller the depth of the contact hole CTH, the greater the extension depth of the contact hole CTH. An extension depth of the first contact hole CTH1 is greater than an extension depth of the n-th contact hole CTHn. According to an embodiment of the present disclosure, in order to extend the contact holes CTH at a uniform depth, a thickness difference between the polymer layers 65 is used.

The first polymer layer 65_1 having a great thickness is formed in the first contact hole CTH1 having a relatively high etch rate, and the n-th polymer layer 65_1 having a small thickness is formed in the n-th contact hole CTHn having a relatively low etch rate. When the contact holes CTH are etched simultaneously in a state in which the polymer layers 65 having different thicknesses are formed as described above, a point in time when the stack ST is exposed may be different for each contact hole CTH. Referring to FIG. 6B, after the etching process is performed for a predetermined time, the polymer layers 65_1 to 65_5 may remain on the bottom surfaces of the first to fifth contact holes CTH1 to CTH5, but the stack ST may be exposed on the bottom surfaces of the sixth to n-th contact holes CTH6 to CTHn. When comparing the first to fifth contact holes CTH1 to CTH5 with each other, the smaller the depths of the first to fifth contact holes CTH1 to CTH5, the greater the thicknesses of the polymer layers 65 remaining on the bottom surfaces of the first to fifth contact holes CTH1 to CTH5 may be. When comparing the sixth to n-th contact holes CTH6 to CTHn with each other, the greater the depths of the sixth to n-th contact holes CTH6 to CTHn, the greater the etching depth of the stack ST may be. As an example, at a point in time when the stack ST is exposed on the bottom surface of the n-th contact hole CTHn, the first polymer layer 65_1 may remain on the bottom surface of the first contact hole CTH1. That is, by forming the first polymer layer 65_1 having the great thickness, it is possible to delay a point in time when the stack ST is exposed in the first contact hole CTH1 having the high etch rate.

Subsequently, referring to FIG. 6C, the contact holes CTH may be extended into the stack ST. When the polymer layers 65_1 to 65_5 are etched in the first to fifth contact holes CTH1 to CTH5 having high etch rates, the stack ST may be etched in the sixth to n-th contact holes CTH6 to CTHn having low etch rates. Because the stack ST is more slowly exposed as the depth of the contact hole CTH becomes smaller, the first contact hole CTH1 having the high etch rate and the n-th contact hole CTHn having the low etch rate may be extended at a uniform depth. Because a difference in etch rate between the contact holes CTH is compensated for by the thickness difference between the polymer layers 65, extension depths ED of the contact holes CTH′ may be the same as each other. In all contact holes CTH′, one layer of the first material layer 61 and one layer of the second material layer 62 may be etched. The extended contact holes CTH′ may have different depths, and the contact holes CTH′ may expose different first material layers 61, respectively.

The polymer layers 65 may remain on sidewalls of the extended contact holes CTH′. A width of an extended portion may be changed depending on a thickness of the remaining polymer layer 65. A width difference between the contact hole CTH and the extended portion may exist by the thickness of the remaining polymer layer 65. When the thickness of the remaining polymer layer 65 is great, the width difference may be great, and when the thickness of the remaining polymer layer 65 is small, the width difference may be small. Referring to FIG. 6D, the photoresist pattern 64 may be removed.

When the photoresist pattern 64 is removed, the remaining polymer layers 65 may be removed together. The extended contact holes CTH′ may have different depths, and may expose the different first material layers 61, respectively.

The extended contact hole CTHn′ may include a first portion P1 that corresponds to the contact hole CTHn and a second portion P2 that is an extended portion. The second portion P2 may have substantially the same width as the first portion P1 or a smaller width than the first portion P1. A step S may exist at a connection point between the first portion P1 and the second portion P2.

Subsequently, formation of polymer layers and extension of the contact holes may be repeatedly performed. Polymer layers may be additionally formed in the extended contact holes CTH′, and the contact holes CTH′ may be additionally extended by etching the additionally formed polymer layers and the stack ST. The additionally formed polymer layers may have different thicknesses depending on depths of the contact holes CTH′. The smaller the depths of the contact holes CTH′, the greater the thicknesses of the polymer layers may be. Through this, the contact holes CTH′ may be uniformly extended at desired depths. In addition, by repeatedly performing a series of processes, extended portions may each have a sidewall with a staircase shape.

Referring to FIG. 6E, insulating layers 66 and sacrificial layers 67 may be formed in the extended contact holes CTH′. The insulating layers 66 may be formed along inner surfaces of the contact holes CTH′, and the contact holes CTH′ may be filled by the sacrificial layers 67. The hard mask pattern 63 may be removed in a process of depositing and planarizing the sacrificial layers 67 and the insulating layers 66. Subsequently, the first material layers 61 may be replaced with

third material layers 68. As an example, openings may be formed by removing the first material layers 61, and conductive layers may be formed in the openings. For example, the conductive layers may be used to form gate lines, and may each include metal such as tungsten (W) or molybdenum (Mo). Through this, a gate structure GST including the second material layers 62 and the third material layers 68 that are alternately stacked may be formed.

For example, when each of the first material layers 61 includes a conductive material, a process of forming the sacrificial layers 67 and a process of replacing the first material layers 61 with the third material layers 68 may be omitted. In such a case, the first material layers 61 may be the gate lines, and the stack ST may be used as the gate structure GST.

Referring to FIG. 6F, the sacrificial layer 67 may be removed. Subsequently, insulating spacers 66A may be formed by etching the insulating layers 66. Subsequently, contact plugs 69 may be formed in the contact holes CTH′, respectively.

According to the manufacturing method described above, the difference in etch rate according to the depth difference between the contact holes CTH may be compensated for through the thicknesses of the polymer layers 65. Accordingly, the contact holes CTH may be extended at a uniform depth.

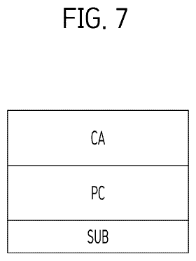

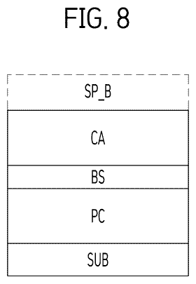

The structures and the manufacturing methods according to the above-described embodiments may be applied to semiconductor devices having various structures. FIGS. 7 and 8 illustrate schematic configurations of semiconductor devices to which the above-described embodiments are applicable.

FIG. 7 is a configuration diagram of a semiconductor device in accordance with an embodiment of the present disclosure.

Referring to FIG. 7, the semiconductor device may include a substrate SUB, a peripheral circuit PC over the substrate, and a memory cell array CA over the peripheral circuit PC. For example, the peripheral circuit PC and the memory cell array CA may be formed on the same substrate.

The substrate SUB may include a semiconductor material. As an example, the semiconductor material may include at least one of a group IV semiconductor, a group III-V compound semiconductor, and a group II-VI compound semiconductor. For example, the group IV semiconductor may include single crystal silicon (Si), polycrystalline silicon, germanium (Ge), or silicon germanium (SiGe). The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. As an example, the substrate SUB may include graphene.

The substrate SUB may be a bulk wafer or an epitaxial layer grown by a selective epitaxial growth (SEG) method. The substrate SUB may be a layer formed by a metal induced lateral crystallization (MILC) method, and may partially include metal. The substrate SUB may have a single crystalline, polycrystalline, or amorphous state. The substrate SUB may include group II, group III, group IV, group V, or group VI impurities. As an example, the substrate SUB may include an n-well region doped with n-type impurities and/or a p-well region doped with p-type impurities.

The peripheral circuit PC may be located between the substrate SUB and the memory cell array CA. The peripheral circuit PC may include a row decoder, a column decoder, a page buffer, a logic circuit, a control circuit, a sense amplifier, an input/output circuit, and the like. As an example, the peripheral circuit PC may include an N-channel metal oxide semiconductor (NMOS) transistor, a P-channel metal oxide semiconductor (PMOS) transistor, a resistor, a capacitor, and the like. The peripheral circuit PC may further include an interconnection structure. The interconnection structure may be used as a path for transmitting an operating voltage and may include a contact plug, a wiring line, and the like.

The memory cell array CA may include memory cells. As an example, the memory cell array CA may include memory strings connected between a source line and a bit line, and each memory string may include stacked memory cells. As an example, the memory cell array CA may include memory cells connected between a word line and the bit line. The memory cell array CA may further include an interconnection structure.

FIG. 8 is a configuration diagram of a semiconductor device in accordance with an embodiment of the present disclosure.

Referring to FIG. 8, the semiconductor device may include a substrate SUB, a peripheral circuit PC over the substrate, a bonding structure BS over the peripheral circuit, and a memory cell array CA over the peripheral circuit. For example, the peripheral circuit PC and the memory cell array CA may be formed on separate substrates, respectively, and then bonded to each other. The semiconductor device may further include a support base SP_B formed over the memory cell array CA.

The substrate SUB may be used as a support in a process of forming the peripheral circuit PC. The support base SP_B may be used as a support in a process of forming the memory cell array CA. As an example, a first wafer including the memory cell array CA and a second wafer including the peripheral circuit PC may be manufactured, respectively, and then electrically connected to each other by the bonding structure BS. After the first wafer and the second wafer are bonded to each other, the support base SP_B of the first wafer may be at least partially removed. The support base SP_B may be completely removed or may partially remain on the memory cell CA array. The support base SP_B may be a semiconductor substrate, an

insulating substrate, a silicon-on-insulator (SOI) substrate, a germanium-on-insulator (GeOI) substrate, or the like. The support base SP_B may be a bulk wafer, an epitaxial layer grown by a selective epitaxial growth (SEG) method, or a layer formed by a metal induced lateral crystallization (MILC) method. The support base SP_B may have a single crystalline, polycrystalline, or amorphous state. The support base SP_B may include group II, group III, group IV, group V, or group VI impurities.

The bonding structure BS may be used to connect the memory cell array CA and the peripheral circuit PC to each other. As an example, the bonding structure BS may bond the memory cell array CA and the peripheral circuit PC to each other by a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper or aluminum and/or alloys thereof. The bonding interface may include a nonmetal-nonmetal interface, a metal-metal interface, or the like. The memory cell array CA and the peripheral circuit PC may be electrically connected to each other by the bonding structure BS.

For example, it is also possible for interconnection structures included in the memory cell array CA and/or the peripheral circuit PC to be directly connected to each other without a bonding pad. As an example, a bonding layer included in the memory cell array CA and a bonding layer included in the peripheral circuit PC may be bonded to each other to form a bonding interface, and an interconnection structure included in the memory cell array CA and an interconnection structure included the peripheral circuit PC may be directly connected to each other. Through this, contact plugs, wiring lines, and the like, formed on different wafers may be electrically connected to each other without a separate bonding pad.

Other configurations may be the same as or similar to those described above with reference to FIG. 7.

It is also possible for the semiconductor device to have a structure in which embodiments described above with reference to FIGS. 7 and 8 are combined with each other or have a partially modified structure. In embodiments described with reference to FIGS. 7 and 8, locations of the memory cell array CA and the peripheral circuit PC may be changed. At least one memory cell array CA and/or at least one peripheral circuit PC may be additionally bonded to each other in an embodiment described with reference to FIG. 7. As an example, a portion of the peripheral circuit PC may be located in the memory cell array CA.

Although embodiments according to the technical idea of the present disclosure have been described above with reference to the accompanying drawings, this is only for describing the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure. Furthermore, the embodiments may be combined to form additional embodiments.

What is claimed is:

1. A semiconductor device comprising:
a gate structure including conductive layers and insulating layers that are alternately stacked;
a first contact plug including a first main portion extended by a first depth through the gate structure and a first extension portion connected to the first main portion and having a sidewall with a staircase shape, the first contact plug being electrically connected to a first conductive layer of the conductive layers; and
a second contact plug including a second main portion extended by a second depth greater than the first depth through the gate structure and a second extension portion connected to the second main portion and having a sidewall with a staircase shape, the second contact plug being electrically connected to a second conductive layer of the conductive layers,
wherein the second extension portion has a greater width than the first extension portion.

2. The semiconductor device of claim 1, wherein the first extension portion and the second extension portion have substantially the same height.

3. The semiconductor device of claim 1, wherein the first contact plug has a step between the first main portion and the first extension portion.

4. The semiconductor device of claim 1, wherein an upper surface of the second main portion has a greater width than an upper surface of the first main portion.

5. The semiconductor device of claim 1, wherein a lower surface of the second extension portion has a greater width than a lower surface of the first extension portion.

6. The semiconductor device of claim 1, wherein heights of respective layers of a staircase shape of the first contact plug and a staircase shape of the second contact plug are the same.

7. The semiconductor device of claim 1, further comprising:
a peripheral circuit;
a first bonding pad electrically connected to the peripheral circuit; and
a second bonding pad electrically connected to the first contact plug and bonded to the first bonding pad.

8. The semiconductor device of claim 1, further comprising:
a first insulating spacer surrounding a sidewall of the first contact plug; and
a second insulating spacer surrounding a sidewall of the second contact plug.
